(19) United States
(12) Patent Application Publication
(10) Pub. No.: US 2018/0342463 A1
(43) Pub. Date: Nov. 29, 2018

(54) CONDUCTIVE ADHESIVE LAYER FOR SEMICONDUCTOR DEVICES AND PACKAGES

(71) Applicant: Intel Corporation, Santa Clara, CA (US)

(72) Inventors: Taylor GAINES, Phoenix, AZ (US); Anna M. PRAKASH, Chandler, AZ (US); Suriyakala RAMALINGAM, Chandler, AZ (US); Boxi LIU, Chandler, AZ (US); Mohit GUPTA, Chandler, AZ (US); Ziv BELMAN, Yokneam Ilit (IL); Baruch SCHIFFMANN, Shoham (IL); Arnon HIRSHBERG, D.N misgav (IL); Vladimir MALAMUD, Hedera (IL); Ron WITTENBERG, Haifa (IL)

(21) Appl. No.: 16/035,048

(22) Filed: Jul. 13, 2018

Related U.S. Application Data
(62) Division of application No. 15/396,415, filed on Dec. 30, 2016.

(51) Int. Cl. H01L 23/552; H01L 23/00; H01L 25/16; H01L 25/00; H01L 23/31; H01L 31/107; H01S 5/022

(52) U.S. Cl. CPC H01L 23/552; H01L 2924/3025; H01L 24/32; H01L 24/83; H01L 25/167; H01L 25/50; H01L 23/3142; H01L 2924/0133; H01L 2224/83851; H01L 2224/8384; H01L 2224/8322; H01L 2224/83191; H01L 2224/32503; H01L 2224/32245; H01L 2224/2919; H01L 2224/29147; H01L 2224/29139; H01L 2224/29113; H01L 2224/29111; H01L 2224/27505; H01L 2224/27418; H01L 2224/27318; H01L 2224/2731; H01L 31/107; H01L 2924/0635; H01L 2924/0665; H01L 2924/12042; H01L 2924/12043; H01L 2924/1434; H01S 5/0226; H01L 24/27

(57) ABSTRACT

In various embodiments this disclosure is directed to conductive adhesives layers that can be used, in one example embodiment, to connect one or more shielding structures (for example, metal cans and/or covers) to a semiconductor package to enclose one or more electronic components on the semiconductor package. In another embodiment, the conductive adhesive layers disclosed herein can be used in connection with optoelectronic devices (for example, optoelectronic devices including laser diodes and/or avalanche photodiodes, APDs). In one embodiment, the conductive adhesives can additionally be used for thermal dissipation and for electrical contact in connection with one or more electronic components on a semiconductor package. In one embodiment, various materials including, spray prints, conductive paste, inks (for example, sintering silver-based materials), epoxy material (for example, epoxy materials filled with silver and/or other metal particles) can be used to provide a conductive adhesive layer.

### CROSS REFERENCE TO RELATED APPLICATIONS

This application is a divisional of U.S. Non-provisional application Ser. No. 15/396,415, filed Dec. 30, 2016, the disclosure of which is incorporated herein by reference in its entireties.

### TECHNICAL FIELD

This disclosure generally relates to conductive adhesive layers, and more particularly to conductive adhesive layer for semiconductor devices and packages.

### BACKGROUND

Electromagnetic interference (EMI) can refer to electronic disturbances generated by an external source that affects an electrical circuit, for example, by electromagnetic induction, electrostatic coupling, and/or conduction. For example, electromagnetic interference at a frequency 2.4 GHz can be caused by 802.11b and 802.11g wireless devices, Bluetooth devices, baby monitors and cordless telephones, video senders, and microwave ovens. The electronic disturbance may degrade the performance of the electrical circuit.

### BRIEF DESCRIPTION OF THE FIGURES

Reference will now be made to the accompanying drawings, which are not necessarily drawn to scale, and wherein:

FIG. 1 shows a diagram of an example shielding structure that can be used to shield one or more electronic components of a semiconductor package, in accordance to one or more example embodiments of the disclosure;

FIG. 2 shows diagrams of an example shielding structure being applied using conductive adhesives to enclose one or more electronic components of a semiconductor package, in accordance with example embodiments of the disclosure;

FIG. 3 shows a photograph of an example conductive adhesive deposited on a molding compound, in accordance with example embodiments of the disclosure;

FIG. 4 shows an example processing flow diagram for the application of a shielding structure using conductive adhesives to enclose one or more electronic components of a semiconductor package, in accordance with example embodiments of the disclosure; and

FIG. 5 shows an example of a system, in accordance with example embodiments of the disclosure.

### DETAILED DESCRIPTION

Embodiments of the disclosure are described more fully hereinafter with reference to the accompanying drawings, in which example embodiments of the disclosure are shown. This disclosure may, however, be embodied in many different forms and should not be construed as limited to the example embodiments set forth herein; rather, these embodiments are provided so that this disclosure will be thorough and complete, and will fully convey the scope of the disclosure to those skilled in the art. Like numbers refer to like, but not necessarily the same or identical, elements throughout.

The following embodiments are described in sufficient detail to enable at least those skilled in the art to understand and use the disclosure. It is to be understood that other embodiments would be evident based on the present disclosure and that process, mechanical, material, dimensional, process equipment, and parametric changes may be made without departing from the scope of the present disclosure.

In the following description, numerous specific details are given to provide a thorough understanding of various embodiments of the disclosure. However, it will be apparent that the disclosure may be practiced without these specific details. In order to avoid obscuring the present disclosure, some well-known system configurations and process steps may not be disclosed in full detail. Likewise, the drawings showing embodiments of the disclosure are semi-diagrammatic and not to scale and, particularly, some of the dimensions are for the clarity of presentation and may be exaggerated in the drawings. In addition, where multiple embodiments are disclosed and described as having some features in common, for clarity and ease of illustration, description, and comprehension thereof, similar and like features will ordinarily be described with like reference numerals even if the features are not identical.

The term “horizontal” as used herein may be defined as a direction parallel to a plane or surface (for example, surface of a substrate), regardless of its orientation. The term “vertical,” as used herein, may refer to a direction orthogonal to the horizontal direction as just described. Terms, such as “on,” “above,” “below,” “bottom,” “top,” “side” (as in “sidewall”), “higher,” “lower,” “upper,” “over,” and “under,” may be referenced with respect to a horizontal plane, where the horizontal plane can include an x-y plane, a x-z plane, or a y-z plane, as the case may be. The term “processing” as used herein includes deposition of material or photoresist, patterning, exposure, development, etching, cleaning, ablating, polishing, and/or removal of the material or photoresist as required in formation a described structure.

In one embodiment, the systems, methods, and apparatus disclosed herein can be used in connection with electronic components, for example, electronic components on a semiconductor package, for example, an optoelectronic package. In one embodiment, the electronic components can include mobile camera modules. In such optoelectronics packages, the light from a diode (for example, an avalanche photodiode, AVP) may be projected onto a scene and then the light that that is reflected back can be collected and processed by one or more processors to generate a digital image. Other non-limiting examples of electronic components that can be used in connection with the disclosure include Central Processing Units (CPUs), logic chips, memory chips, LTE chips, Bluetooth chips, Wi-Fi chips, photodetectors, and/or sensors.

In one embodiment, semiconductor packages may include different portions associated one or more electronic components of the semiconductor package where electromagnetic (for example, radio-frequency, RF) shielding at predetermined frequencies ranges may be needed. In one embodiment, a shielding structure (for example, a metallic can) can be used to enclose various portions of the semiconductor package to provide shielding for one or more electronic components (for example, one or more detectors and/or optoelectronic devices) on the semiconductor package.

In one embodiment, disclosed herein are conductive adhesives layers that can be used, in one example embodiment, to connect one or more shielding structures (for example, metal cans and/or covers) to a semiconductor package. In another embodiment, the conductive adhesives disclosed herein can be used in connection with optoelectronic devices (for example, optoelectronic devices including laser diodes and/or avalanche photodiodes, APDs).

In one embodiment, the conductive adhesives can additionally be used for thermal dissipation and for electrical contact in connection with one or more electronic components on a semiconductor package. In another embodiment, the conductive adhesive layer can be used in connection with one or more low power devices that may need thermal conductance through the conductive adhesive layer. In one embodiment, the conductive adhesive layer can be used to allow shielding structures to connect with a semiconductor package.

In one embodiment, the optoelectronic devices can include an avalanche photodiode (APD). In one embodiment, the conductive adhesives can be used to provide electrical and thermal conduction for the APD. In addition, the conductive adhesives can be used to connect a shielding structure to at least partially enclose the APD. Further, in one embodiment, the conductive adhesive layer can be used to ground one or more electronic components (for example, one or more laser diodes and/or APDs).

In one embodiment, the conductive adhesives can be applied using soldering, for example, laser soldering. However, optoelectronic components and packages may be sensitive to temperature and the high amounts of energy, for example, that may be used in soldering. Additionally, soldering may require the use of flux and deflux procedures, which can add moisture to the semiconductor package (for example, optoelectronic components and packages). In one embodiment, the conductive adhesives disclosed herein can be cured at comparatively low temperatures (for example, temperatures below approximately 75 C).

In one embodiment, the conductive adhesives disclosed herein can withstand a loss of conductivity with stress, time, temperature and humidity exposure. The reduction in the losses can reduce failures associated with the electronic components and/or semiconductor package performance. For example, with laser diodes, a reduction in the conductivity of the conductive adhesive over time can lead to the laser diode's signal intensity to fluctuate, thereby affecting the laser diode's optical performance. In the case of APDs, environmental stress can also lead to a reduction in the optical performance over time. In one embodiment, a degradation of the conductivity of the conductive adhesive, then the shielding structure can have a reduced shielding effectiveness.

In one embodiment, lower temperature conductive adhesives can include sintered metals (for example, silver) that can have a sintering temperature of approximately 75 degrees C. and below. Accordingly, one or more electronic components do not necessarily get exposed to as high of temperatures during annealing, curing, and/or sintering processes. Rather a conductive electrical and thermal connection can be achieved, for example, between the ground pads and the shielding structure by using the conductive adhesive layer.

Currently, conductive adhesives may require a relatively high (for example, approximately 150 degree C.) and approximately an hour to cure the conductive adhesives. At such high temperatures at least portions of a semiconductor package (for example, an optoelectronic packages including, for example, lenses) can melt or otherwise be damaged. As such, a low temperature sinterable adhesive, for example, a conductive, sinterable metal (for example, silver, copper) nanoparticle adhesive can be used that sinters at approximately 75 degrees C. in approximately 15 minutes. In one embodiment, a multiple metal (for example, a copper-tin) intermetallic compound (IMC) can be used as a low temperature adhesive. In such cases, the metals can be melted together and to form an intermetallic, that can have a higher melting temperature, but still low enough to not damage the semiconductor package and/or the electronic components thereon.

In one embodiment, the conductive sinterable metal (for example, silver, copper) nanoparticle adhesive can be cured using a photonic curing method. Photonic curing can refer to the high-temperature thermal processing of the conductive adhesive using pulsed light, for example, pulsed light from a flashlamp. Photonic curing may allow the conductive adhesive to be cured much more rapidly than with an oven.

In one embodiment, one or more electronic components on a semiconductor package may emit electromagnetic radiation at various frequencies. For example, low frequency radiation (below approximately 1 GHz) can be emitted by switches, motors, power supplies, and transformers. As another example, higher frequency (for example, approximately 1 GHz to approximately 10 GHz frequencies) radiation can be emitted by components including CPUs or logic chips, memory chips, LTE chips, Bluetooth chips, Wi-Fi chips. Such radiation may need to be attenuated to reduce interference with electronic components that are exposed to the radiation.

Accordingly, in various embodiments, a shielding structure can be used to enclose one or more electronic components on the semiconductor package to provide RF shielding for those electronic components. In one embodiment, the shielding can also be used to provide shielding for the other portions of semiconductor package that may not be immediately proximate to the one or more electronic components to be shielded. For example, shielding can be used to protect portions of the semiconductor package having electronic components that have a larger distance to the electronic components having the shielding. Alternatively or additionally, shielding can be used to protect electronic components on an adjacent board proximate to the board housing the semiconductor package having the shielding.

In one embodiment, various materials including, spray prints, conductive paste, inks (for example, sintering silver-based materials), epoxy material (for example, epoxy materials filled with silver and/or other metal particles) can be used to provide a conductive adhesive layer that can be used, for example, for the application of the shielding structure. For example, the conductive adhesive layer can serve to affix, secure or connect the shielding structure to a printed circuit board (PCB) and/or a molding compound associated with a semiconductor package.

In one embodiment, the materials to be used as the conductive adhesive layer can include sintering nanoparticles (for example, silver, copper, and other metal nanoparticles) can be used as the conductive adhesive layer. In one embodiment, non-sintering pastes and/or inks (for example, non-sintering pastes and/or inks containing metals such as Ag, Cu, Ni, Fe) in an epoxy, acrylic, or other polymer formulation can be used for the conductive adhesive layer. In one embodiment, intermetallic compound-forming materials (such as SnBiCu pastes), and/or conductive particles (such as fibers, flakes, nanoparticles, graphite, and the like) can be used for the conductive adhesive layer.

In various embodiments a variety of techniques including spraying techniques (including atomization, electrospray, and/or ultrasonic spraying techniques) can be used to deposit the conductive adhesive layer. In another embodiment, plating (including, for example, electrolytic and electroless plating), printing (including, for example, vacuum printing and/or conventional printing), and/or dispense techniques (including, for example, Auger and/or jet dispensing) techniques can be used to deposit the conductive adhesive layer.

In one embodiment, the material(s) used for the shielding structure and/or the conductive adhesive layer can be selected to provide shielding at approximately 2.4 to approximately 5 GHz frequency range. In another embodiment, the material(s) used for the shielding structure and/or the conductive adhesive layer can be selected to provide shielding at comparatively lower frequency ranges (for example, shielding from radiation having a frequency in the MHz range).

In one embodiment, for comparatively lower frequency shielding, the shielding material for the shielding structure and/or the conductive adhesive layer can be selected based at least in part on the shielding material's magnetic permeability. In one embodiment, iron can be used for the shielding material of the shielding structure. In another embodiment, the resistivity of the shielding material may not as important of a consideration as the magnetic permeability of the shielding material for the shielding structure for use in comparatively lower frequency applications. In one embodiment, the lower-frequency shielding structure can reduce RF interference from power lines or similar structures in the environment of the shielded electronic components and/or the shielded semiconductor package.

In one embodiment, the conductive adhesive layer can be deposited using a spray technique. In one embodiment, the spray technique can include, for example, an atomization spray, an ultrasonic spray, and/or an electrospray technique. In another embodiment, the atomization spray, ultrasonic spray, and/or the electro spray technique can serve to create finer and finer particles that can lead to the fabrication of a more uniform and defect-free conductive adhesive layer.

In one embodiment, the conductive adhesive layer can additionally be deposited using a dispensing and/or printing technique. For example, the printing technique can include a conventional printing technique. In one embodiment, the printing technique can further include a vacuum printing technique, which can serve to reduce the generation of voids in the conductive adhesive layer. In one embodiment, vacuuming print can be used for filling fine spaces and/or trenches between one or more electronic components on the semiconductor package. In one embodiment, the dispensing technique can include Auger dispensing technique and/or a jet dispensing technique. In one embodiment, the Auger dispensing technique can resemble a drill-type mechanism.

In one embodiment, the conductive adhesive layer can have a thickness of approximately 1 micron to 10 microns, which example thickness of approximately 3 microns to approximately 5 microns. In another embodiment, the thickness of the conductive adhesive layer can be on the order of approximately 5 nanometers to approximately 1000 nanometers.

In one embodiment, the conductive adhesive layer can include a conductive paste or a conductive polymer. In another embodiment, the conductive adhesive layer can include an adhesive property. In one embodiment, the adhesive property can be reduced by the application of a thermal curing process. In one embodiment, the conductive adhesive layer can include a metal that uses silver nanoparticles.

In one embodiment, the shielding structure can be physically and electronically coupled to one or more ground pads on the semiconductor package, the ground pads being covered with the conductive adhesive layer.

In one embodiment, the lower the resistivity of the conductive adhesive layer, the higher the conductivity of the conductive adhesive layer. In one embodiment, the higher the conductivity and/or the lower the resistivity, the better the conductive adhesive layer can shield the electronic components and/or the semiconductor package.

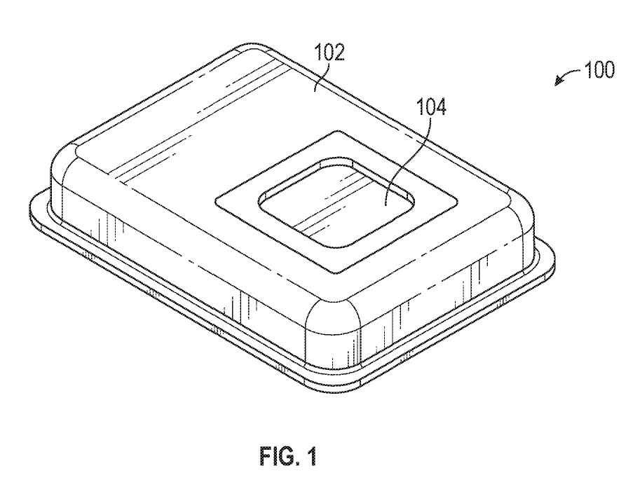

FIG. 1 shows a diagram of an example shielding structure 100, in accordance with example embodiments of the disclosure. In one embodiment, the shielding structure 100 can be used in connection with one or more electronic components and/or semiconductor packages. For example, the shielding structure 100 can be used to shield one or more electronic components associated with an optoelectronic device. For example, shielding structure that can be attached using a conductive adhesive layer in accordance with one or more example embodiments described herein. In one embodiment, the conductive adhesive layer can be deposited onto one or more grounding pads on a PCB and the shielding structure can be mechanically contacted with the conductive adhesive layer.

In one embodiment, the shielding structure 100 can include a semi-transparent layer (for example, a glass layer) 104. The semi-transparent layer 104 may permit the at least partial transmission of electromagnetic radiation at a predetermined frequency or frequency range. For example, for a shielding structure 100 used to shield one or more electronic components associated with an optoelectronic device, the semi-transparent layer 104 can be used to permit the at least partial transmission of electromagnetic radiation in the visible part of the electromagnetic spectrum. As such the shielding structure may permit the optoelectronic device and/or package to transmit and/or capture light, for example, for the generation of a digital image and/or a video. The semi-transparent layer can be sized and shape, and located on the shielding structure, in a manner to conform to a particular application.

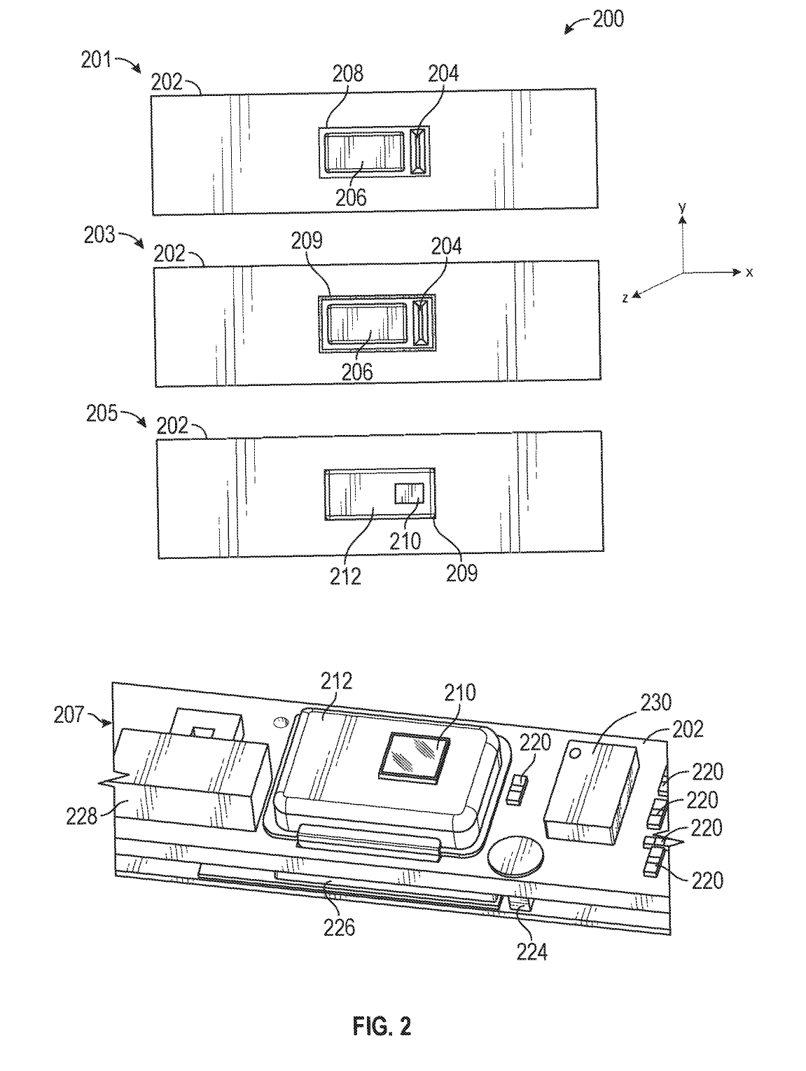

FIG. 2 shows example views of a portion of a semiconductor package having several electronic components that can be shielded using a shielding structure, in accordance to one or more example embodiments of the disclosure. In one embodiment, the electronic components can be separated by a predetermined space on the order of several microns.

In particular, diagram 201 shows a portion of a semiconductor package (for example, a semiconductor package including an optoelectronic device) from a top view, further showing several electronic components (for example the electronic components 204 and 206) mounted on a PCB board 202. The portion of the semiconductor package shown in diagram 201 can further include a molding compound (not shown), a first electronic component (for example, an APD) 204, a second electronic component (for example, a laser diode and/or a memory device) 206. In an embodiment, the electronic components (for example the electronic components 204 and 206) on the portion of the semiconductor package shown in diagram 201 have not had the application of any shielding (for example, by a shielding structure). In one embodiment, ground pads 208 are also present and shown on the diagram 201. These ground pads can be used in connection with the conductive adhesive, discussed below. In one embodiment, the electronic components (for example, electronic components 204 and 206) on the semiconductor package can be disposed in molding compound or material. In one embodiment, the molding material can include an epoxy-based or an underfill material that can provide mechanical stability to the electronic components on semiconductor.

In one embodiment, while only two electronic components are shown in diagram 201, there may be approximately hundreds of electrical components on a given semiconductor package (for example, a semiconductor package including an optoelectronic device), but not every electronic component may need to be shielded. For example, there may be a predetermined number of electronic components (for example, three to four electronic components) that may need to be shielded from electromagnetic radiation at predetermined frequencies. In one embodiment, the semiconductor (for example, optoelectronic) package used in connection with this disclosure may be approximately 70 cm by approximately 3 cm in area.

In one embodiment, depending on what frequency range the electronic components may need to be to be shielded, the type of shielding material for the shielding structure applied to enclose the electronic components and/or semiconductor package can vary. For example, the shielding material for the shielding structure can include a nickel and/or iron-based material.

Diagram 203 also shows a portion of a semiconductor package (for example, a semiconductor package including an optoelectronic device) from a top view, further showing several electronic components (for example the electronic components 204 and 206) mounted on a PCB board 202. The portion of the semiconductor package shown in diagram 203 can further include a molding compound (not shown), a first electronic component (for example, an avalanche photodiode, AVP) 204, a second electronic component (for example, a laser diode and/or a memory device) 206. In an embodiment, the electronic components (for example the electronic components 204 and 206) on the portion of the semiconductor package shown in diagram have not had the application of any shielding (for example, by a shielding structure). In one embodiment, a conductive adhesive layer 209 can be deposited on the grounding pads 208. In one embodiment, the conductive adhesive layer 209 can be used to affix a shielding structure (to be discussed below) to enclose one or more electronic components (for example, the electronic components 204 and 206) of the semiconductor package.

In one embodiment, various materials including, spray prints, conductive paste, inks (for example, sintering silver-based materials), epoxy material (for example, epoxy materials filled with silver and/or other metal particles) can be used to provide a conductive adhesive layer 209 that can be used, for example, for the application of the shielding structure. For example, the conductive adhesive layer 209 can serve to connect the shielding structure to the PCB 202 and/or a molding compound (not shown) associated with a semiconductor package.

In one embodiment, the materials to be used as the conductive adhesive layer 209 can include sintering nanoparticles (for example, silver, copper, and other metal nanoparticles) can be used as the conductive adhesive layer 209. In one embodiment, non-sintering pastes and/or inks (for example, non-sintering pastes and/or inks containing metals such as Ag, Cu, Ni, Fe) in an epoxy, acrylic, or other polymer formulation can be used for the conductive adhesive layer. In one embodiment, intermetallic compound-forming materials (such as SnBiCu pastes), and/or conductive particles (such as fibers, flakes, nanoparticles, graphite, and the like) can be used for the conductive adhesive layer 209.

In various embodiments a variety of techniques including spraying techniques (including atomization, electrospray, and/or ultrasonic spraying techniques) can be used to deposit the conductive adhesive layer 209. In another embodiment, plating (including, for example, electrolytic and electroless plating), printing (including, for example, vacuum printing and/or conventional printing), and/or dispense techniques (including, for example, Auger and/or jet dispensing) techniques can be used to deposit the conductive adhesive layer 209.

In one embodiment, the materials used for the conductive adhesive layer 209 can include sinterable metal samples and/or non-sinterable metal samples that can be suspended in solution or a polymer. In one embodiment, one or more trenches (not shown) between electronic components (for example, electronic components 204 and 206) on the semiconductor package can be filled with the conductive adhesive layer 209 using a printing and/or dispensing technique or dispensed into the trench (not shown).

In one embodiment, while only two electronic components are shown in diagram 201, there may be approximately hundreds of electrical components on a given semiconductor package (for example, a semiconductor package including an optoelectronic device), but not every electronic component may need to be shielded. For example, there may be a predetermined number of electronic components (for example, three to four electronic components) that may need to be shielded from electromagnetic radiation at predetermined frequencies. In one embodiment, the semiconductor (for example, optoelectronic) package used in connection with this disclosure may be approximately 70 cm by approximately 3 cm in area.

In one embodiment, depending on what frequency the electronic components may need to be to be shielded, the type of shielding material for the shielding structure applied to enclose the electronic components and/or semiconductor package can vary. For example, the shielding material for the shielding structure can include a nickel and/or iron-based material.

In an embodiment, diagram 205 shows the portion of the semiconductor package (for example, the semiconductor package as shown and described in connection with diagrams 201 and 203) after being shielded with a shielding structure 212. In one embodiment, the conductive adhesive layer 209 can be deposited onto one or more grounding pads (for example, grounding pads 208 of diagram 201) on a PCB 202 and the shielding structure 212 can be mechanically contacted with the conductive adhesive layer 209.

In one embodiment, the shielding structure 212 can include a semi-transparent layer (for example, a glass layer) 210. The semi-transparent layer 210 may permit the at least partial transmission of electromagnetic radiation at a predetermined frequency or frequency range. For example, for a shielding structure 212 used to shield one or more electronic components associated with a semiconductor package comprising an optoelectronic device and/or package, the semi-transparent layer 104 can be used to permit the at least partial transmission of electromagnetic radiation in the visible part of the electromagnetic spectrum. As such the shielding structure 212 may permit the optoelectronic device and/or package to transmit and/or capture light, for example, for the generation of a digital image and/or a video.

In one embodiment, the material(s) used for the shielding structure 212 and/or the conductive adhesive layer can be selected to provide shielding at approximately 2.4 to approximately 5 GHz frequency range. In another embodiment, the material(s) used for the shielding structure and/or the conductive adhesive layer can be selected to provide shielding at comparatively lower frequency ranges (for example, shielding from radiation having a frequency in the MHz range).

In one embodiment, for comparatively lower frequency shielding, the shielding material for the shielding structure 212 and/or the conductive adhesive layer 209 can be selected based at least in part on the shielding material's magnetic permeability. In one embodiment, iron can be used for the shielding material of the shielding structure 212. In another embodiment, the resistivity of the shielding material may not be as important of a consideration as the magnetic permeability of the shielding material for the shielding structure 212 for use in comparatively lower frequency applications. In one embodiment, the lower-frequency shielding structure 212 can reduce RF interference from power lines or similar structures in the environment of the shielded electronic components (for example, electronic components 204 and 206 shown in diagrams 201 and 202) and/or the shielded semiconductor package.

In one embodiment, the shielding structure 212 can be used in connection with high-frequency switching electronic components, such as memory, Bluetooth, Wi-Fi, and/or LTE modules. Such high-frequency switching electronic components may need to be shielded to reduce interference with the optoelectronic package and/or device(s) on a semiconductor package including a camera module (not shown).

Diagram 207 shows a three-dimensional rendering of a portion of the semiconductor package (for example, the semiconductor package as shown and described in connection with diagrams 201 and 203) including one or more electronic components on a PCB 202, after the application of the shielding structure 212. In one embodiment, the conductive adhesive layer 209 can be deposited onto one or more grounding pads (for example, grounding pads 208 of diagram 201) on a PCB 202 and the shielding structure 212 can be mechanically contacted with the conductive adhesive layer 209. Further shown on diagram 207 are additional example electronic components 220, 228, and 230 that can also be shielded from the radiation emanating from the electronic components enclosed by the shielding structure 212. Alternatively or additionally, the electronic components enclosed by the shielding structure 212 can be shielded from the radiation emanating from the example electronic components 220, 228, and 230. In one embodiment, various other electrical and mechanical connection points and/or supporting structures may exist on the semiconductor package, for example, the electrical and mechanical connection points and/or supporting structures 224 and/or 226.

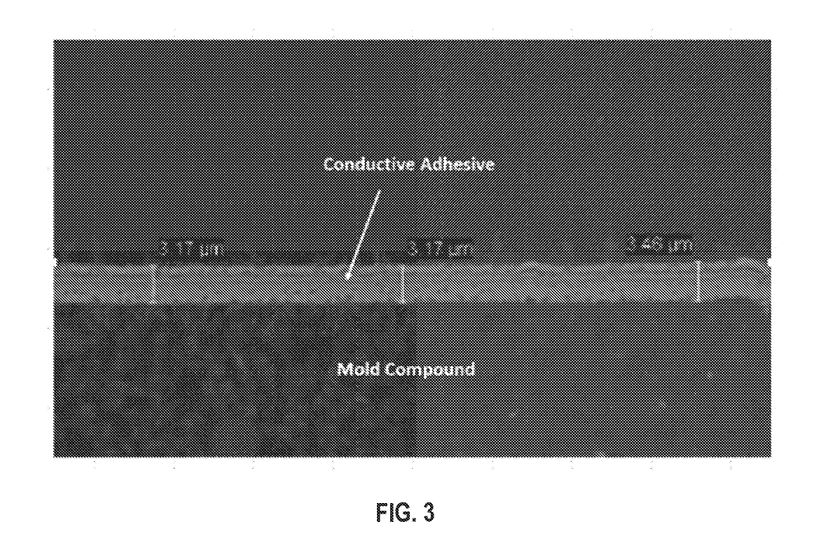

FIG. 3 shows a photograph of an example fabricated conductive adhesive layer 302 deposited on a molding compound 304, in accordance with example embodiments of the disclosure. In one embodiment, the lower the resistivity of the conductive adhesive layer 302, the higher the conductivity of the conductive adhesive layer 302. In one embodiment, the higher the conductivity and/or the lower the resistivity, the better the conductive adhesive layer 302 can shield the electronic components and/or the semiconductor package.

In one embodiment, the molding compound's 304 surface can be plasma treated prior to the application of the conductive adhesive layer 302. In one embodiment, the plasma treatment can serve to roughen the molding compound's surface, thereby allowing for better adhesion.

In one embodiment, the conductive adhesive layer 302 can be deposited using a spray technique. In one embodiment, the spray technique can include, for example, an atomization spray, an ultrasonic spray, and/or an electrospray technique. In another embodiment, the atomization spray, ultrasonic spray, and/or the electrospray technique can serve to create finer and finer particles that can lead to the fabrication of a more uniform and defect-free conductive adhesive layer 302.

In one embodiment, the conductive adhesive layer 302 can additionally be deposited using a dispensing and/or printing technique. For example, the printing technique can include a conventional printing technique. In one embodiment, the printing technique can further include a vacuum printing technique, which can serve to reduce the generation of voids in the conductive adhesive layer 302. In one embodiment, vacuuming print can be used for filling fine spaces and/or trenches between electronic components on the semiconductor package that this conductive adhesive layer 302 can be part. In one embodiment, the dispensing technique can include Auger dispensing technique and/or a jet dispensing technique. In one embodiment, the Auger dispensing technique can resemble a drill-type mechanism.

In one embodiment, for a conductive adhesive layer 302 deposited using a dispensing and/or printing technique, there may be a post-deposition thermal curing step. optionally be annealed. In one embodiment, the annealing and/or curing can include curing and/or sintering at a temperature range of approximately 75 degrees Centigrade to approximately 200 degrees Centigrade. In one embodiment, the lower the temperature of the thermal curing and/or or annealing, the less disruptive the heat may be to the components of the semiconductor package (for example, optoelectronics packages including, for example, components including lenses, MEMS, and/or magnets).

In one embodiment, the electronic components on the semiconductor package can be disposed in molding compound 304. In one embodiment, the molding compound 304 can include an epoxy-based or an underfill material that can provide mechanical stability to the electronic components on semiconductor.

In one embodiment, the conductive adhesive layer 302 can having a thickness of approximately 1 micron to 10 microns, which example thickness of approximately 3 microns to approximately 5 microns. In another embodiment, the thickness of the conductive adhesive layer 302 can be on the order of approximately 5 nanometers to approximately 1000 nanometers. In one embodiment, the thickness of the conductive adhesive layer 302 can depend on the frequency range for shielding and/or the material(s) used for shielding. For a conductive adhesive layer 302 used for shielding of electromagnetic radiation at approximately 5 GHz, the conductive adhesive layer 302 can have a thickness of approximately 2 microns. In one embodiment, for many electronic components requiring shielding for radiation from a range of approximately 1 GHz and above, approximately 4 micron to approximately 5 microns of conductive adhesive layer 302 may be used.

In one embodiment, the conductive adhesive layer 302 can include a conductive paste or a conductive polymer. In one embodiment, the adhesive property of the conductive adhesive layer 302 can be reduced by the application of the thermal curing process. In one embodiment, the conductive adhesive layer 302 can include a metal that uses silver nanoparticles.

In one embodiment, for a conductive adhesive layer 302 including conductive pastes and/or inks, the molding compound's surface can be plasma treated prior to the application of the conductive paste and/or ink. In one embodiment, the plasma treatment can serve to roughen the molding compound's 304 surface, thereby allowing for better adhesion.

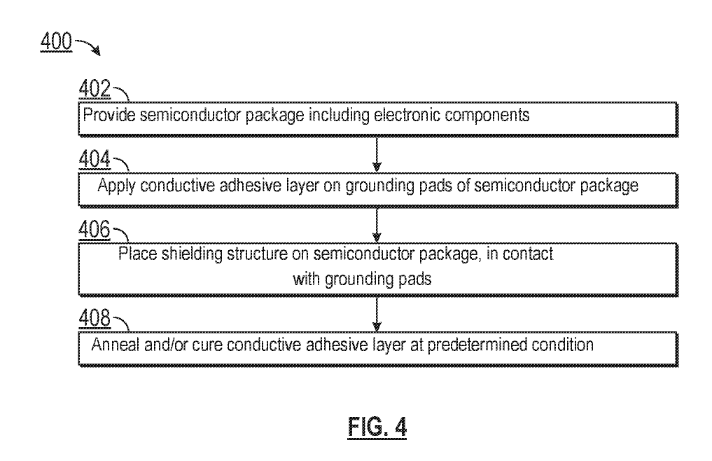

FIG. 4 shows an example processing flow diagram for the fabrication of the conductive adhesive layer and the application of the shielding structure using the conductive adhesive layer to enclose one or more electronic components of a semiconductor package (for example, an optoelectronic device and/or package), in accordance with example embodiments of the disclosure.

In block 402, a portion of a semiconductor package including one or more electronic components can be provided. In one embodiment, the shielding systems, methods, and apparatus disclosed herein can be used in connection with electronic components, for example, electronic components on a semiconductor package. In one embodiment, the electronic components can include built-in mobile camera modules. In another embodiment, the systems, methods, and apparatus disclosed herein can be used in connection with semiconductor packages, for example, with optoelectronics packages. In such optoelectronics packages, the light from a diode may be projected onto a scene and then the light that is reflected back can be collected and processed by one or more processors to generate an image. Other non-limiting examples of electronic components that can be used in connection with the disclosure include Central Processing Units (CPUs), logic chips, memory chips, LTE chips, Bluetooth chips, Wi-Fi chips, photodetectors, and/or sensors.

In one embodiment, semiconductor packages may include different portions associated one or more electronic components of the semiconductor package where electromagnetic (for example, radio-frequency, RF) shielding at predetermined frequencies ranges may be needed. In one embodiment, a can (for example, a metallic can) can be used to enclose various portions of the semiconductor package to provide shielding for one or more electronic components (for example, one or more detectors and/or optoelectronic packages and/or devices) on the semiconductor package.

In one embodiment, one or more electronic components on a semiconductor package may emit electromagnetic radiation at various frequencies. For example, low frequency radiation (below approximately 1 GHz) can be emitted by switches, motors, power supplies, and transformers. As another example, higher frequency (for example, approximately 1 GHz to approximately 10 GHz frequencies) radiation can be emitted by components including CPUs or logic chips, memory chips, LTE chips, Bluetooth chips, Wi-Fi chips. Such radiation may need to be attenuated to reduce interference with electronic components that are exposed to the radiation.

In block 404, a conductive adhesive layer can be applied on grounding pads on the semiconductor package. In one embodiment, the conductive adhesive layer can be used to affix a shielding structure (to be discussed below) to enclose one or more electronic components of the semiconductor package.

In one embodiment, various materials including, spray prints, conductive paste, inks (for example, sintering silver-based materials), epoxy material (for example, epoxy materials filled with silver and/or other metal particles) can be used to provide a conductive adhesive layer that can be used, for example, for the application of the shielding structure. For example, the conductive adhesive layer can serve to connect the shielding structure to the PCB and/or a molding compound associated with a semiconductor package.

In one embodiment, the materials to be used as the conductive adhesive layer can include sintering nanoparticles (for example, silver, copper, and other metal nanoparticles) can be used as the conductive adhesive layer. In one embodiment, non-sintering pastes and/or inks (for example, non-sintering pastes and/or inks containing metals such as Ag, Cu, Ni, Fe) in an epoxy, acrylic, or other polymer formulation can be used for the conductive adhesive layer. In one embodiment, intermetallic compound-forming materials (such as SnBiCu pastes), and/or conductive particles (such as fibers, flakes, nanoparticles, graphite, and the like) can be used for the conductive adhesive layer.

In various embodiments a variety of techniques including spraying techniques (including atomization, electrospray, and/or ultrasonic spraying techniques) can be used to deposit the conductive adhesive layer. In another embodiment, plating (including, for example, electrolytic and electroless plating), printing (including, for example, vacuum printing and/or conventional printing), and/or dispense techniques (including, for example, Auger and/or jet dispensing) techniques can be used to deposit the conductive adhesive layer.

In one embodiment, the materials used for the conductive adhesive layer can include sinterable metal samples and/or non-sinterable metal samples that can be suspended in solution or a polymer. In one embodiment, a low temperature sinterable adhesive, for example, a conductive, sinterable metal (for example, silver, copper) nanoparticle adhesive can be used that sinters at approximately 75 degrees C. in approximately 15 minutes. In one embodiment, a multiple metal (for example, a copper-tin) intermetallic compound (IMC) can be used as a low temperature adhesive. In such cases, the metals can be melted together and to form an intermetallic, that can have a higher melting temperature, but still low enough to not damage the semiconductor package and/or the electronic components thereon.

In block 406, a shielding structure can be placed on the semiconductor package in contact with the conductive adhesive layer to enclose the one or more electronic components. In one embodiment, the shielding structure can include a semi-transparent layer (for example, a glass layer). The semi-transparent layer may permit the at least partial transmission of electromagnetic radiation at a predetermined frequency or frequency range. For example, for a shielding structure used to shield one or more electronic components associated with a semiconductor package comprising an optoelectronic device and/or package, the semi-transparent layer can be used to permit the at least partial transmission of electromagnetic radiation in the visible part of the electromagnetic spectrum. As such the shielding structure may permit the optoelectronic device and/or package to transmit and/or capture light, for example, for the generation of a digital image and/or a video.

In one embodiment, the material(s) used for the shielding structure and/or the conductive adhesive layer can be selected to provide shielding at approximately 2.4 to approximately 5 GHz frequency range. In another embodiment, the material(s) used for the shielding structure and/or the conductive adhesive layer can be selected to provide shielding at comparatively lower frequency ranges (for example, shielding from radiation having a frequency in the MHz range).

In one embodiment, for comparatively lower frequency shielding, the shielding material for the shielding structure and/or the conductive adhesive layer can be selected based at least in part on the shielding material's magnetic permeability. In one embodiment, iron can be used for the shielding material of the shielding structure. In another embodiment, the resistivity of the shielding material may not as important of a consideration as the magnetic permeability of the shielding material for the shielding structure for use in comparatively lower frequency applications. In one embodiment, the lower-frequency shielding structure can reduce RF interference from power lines or similar structures in the environment of the shielded electronic components and/or the shielded semiconductor package.

In one embodiment, the shielding structure can be used in connection with high-frequency switching electronic components, such as memory, Bluetooth, Wi-Fi, and/or LTE modules. Such high-frequency switching electronic components may need to be shielded to reduce interference with the optoelectronic package and/or device(s) on a semiconductor package including a camera module.

In block 408, an anneal and/or cure of the conductive adhesive layer at predetermined conditions can be performed. In one embodiment, the annealing and/or curing can include curing and/or sintering at a temperature range of approximately 75 degrees Centigrade to approximately 200 degrees Centigrade. In one embodiment, the lower the temperature, the less disruptive the heat may be to the components of the semiconductor package (for example, optoelectronics packages including, for example, components including lenses, MEMS, and/or magnets).

In one embodiment, for conductive adhesive layer comprising a conductive sinterable metal (for example, silver, copper) nanoparticle adhesive, the conductive adhesive layer can be cured using a photonic curing method. Photonic curing can refer to the high-temperature thermal processing of the conductive adhesive using pulsed light, for example, pulsed light from a flashlamp. Photonic curing may allow the conductive adhesive layer to be cured much more rapidly than with an oven.

In various embodiments a semiconductor package having one or more electronic components disposed thereon can be used in connection with the disclosure. The electronic components may include, but not be limited to, integrated circuits, surface mount devices, active devices, passive devices, diodes, transistors, connectors, resistors, inductors, capacitors, microelectromechanical systems (MEMS), combinations thereof, or the like. The electronic components may be electrically and mechanically coupled to the semiconductor package substrate via any suitable mechanism, such as metal pillars (e.g., copper pillars), flip chip bumps, solder bumps, any type of low-lead or lead-free solder bumps, tin-copper bumps, wire bonds, wedge bonds, controlled collapse chip connects (C4), anisotropic conductive film (ACF), nonconductive film (NCF), combinations thereof, or the like.

The ground pads may be extensions of a ground plane that may be, in example embodiments, a build-up layer (for example, a build-up layer with interconnects) within the semiconductor package substrate. When the semiconductor package is in operation, the ground plane may be shorted to ground, such as on a printed circuit board (PCB) on which the semiconductor package is disposed. The ground plane may be electrically connected, in example embodiments, to one or more ground pads. The ground pads may include one or more pads and/or interconnect traces (e.g., surface wiring traces) on the top surface of the semiconductor package.

In various embodiments, the substrate associated with the semiconductor package may be of any suitable size and/or shape. For example, the substrate associated with the semiconductor package, in example embodiments, may be a rectangular panel. In example embodiments, the substrate associated with the semiconductor package may be fabricated of any suitable material, including polymer material, ceramic material, plastics, composite materials, glass, epoxy laminates of fiberglass sheets, FR-4 materials, FR-5 materials, combinations thereof, or the like. the substrate associated with the semiconductor package may have a core layer and any number of interconnect build-up layers on either side of a core layer. The core and/or the interconnect build-up layers may be any variety of the aforementioned materials and, in some example embodiments, may not be constructed of the same material types. It will be appreciated that the build-up layers may be fabricated in any suitable fashion. For example a first layer of build-up interconnect may include providing a package substrate core, with or without through holes formed therein. Dielectric laminate material may be laminated on the semiconductor substrate core material. Vias and/or trenches may be patterned in the build-up layer using any suitable mechanism, including photolithography, plasma etch, laser ablation, wet etch, combinations thereof, or the like. The vias and trenches may be defined by vertical and horizontal metal traces, respectively within the build-up layer. The vias and trenches may then be filled with metal, such as by electroless metal plating, electrolytic metal plating, physical vapor deposition, combinations thereof, or the like. Excess metal may be removed by any suitable mechanism, such as etch, clean, polish, and/or chemical mechanical polish (CMP), combinations thereof, or the like. Subsequent build-up layers (e.g., higher levels of build-up layers) on either side of the core may be formed by the same aforementioned processes.

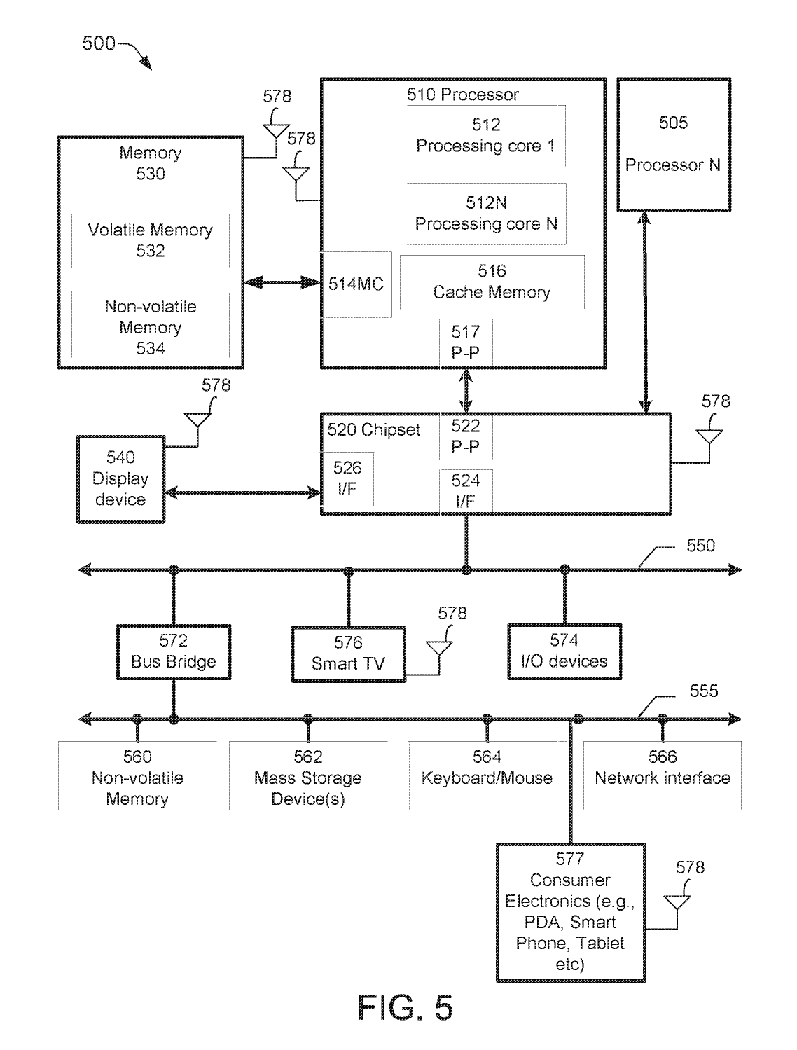

FIG. 5 depicts an example of a system 500 according to one or more embodiments of the disclosure. In one embodiment, the shielding structures disclosed herein can be used to provide electromagnetic (for example, radio frequency, RF) shielding for one or more devices shown and described in FIG. 5. In one embodiment, system 500 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 500 can include a system on a chip (SOC) system.

In one embodiment, system 500 includes multiple processors including processor 510 and processor N 505, where processor N 505 has logic similar or identical to the logic of processor 510. In one embodiment, processor 510 has one or more processing cores (represented here by processing core 1 512 and processing core N 512N, where 512N represents the Nth processor core inside processor 510, where N is a positive integer). More processing cores can be present (but not depicted in the diagram of FIG. 5). In some embodiments, processing core 512 includes, but is not limited to, pre-fetch logic to fetch instructions, decode logic to decode the instructions, execution logic to execute instructions, a combination thereof, or the like. In some embodiments, processor 510 has a cache memory 516 to cache instructions and/or data for system 500. Cache memory 516 may be organized into a hierarchical structure including one or more levels of cache memory.

In some embodiments, processor 510 includes a memory controller (MC) 514, which is configured to perform functions that enable the processor 510 to access and communicate with memory 530 that includes a volatile memory 532 and/or a non-volatile memory 534. In some embodiments, processor 510 can be coupled with memory 530 and chipset 520. Processor 510 may also be coupled to a wireless antenna 578 to communicate with any device configured to transmit and/or receive wireless signals. In one embodiment, the wireless antenna 578 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 532 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 534 includes, but is not limited to, flash memory, phase change memory (PCM), read-only memory (ROM), electrically erasable programmable read-only memory (EEPROM), or any other type of non-volatile memory device.

Memory device 530 stores information and instructions to be executed by processor 510. In one embodiment, memory 530 may also store temporary variables or other intermediate information while processor 510 is executing instructions. In the illustrated embodiment, chipset 520 connects with processor 510 via Point-to-Point (PtP or P-P) interface 517 and P-P interface 522. Chipset 520 enables processor 510 to connect to other elements in system 500. In some embodiments of the disclosure, P-P interface 517 and P-P interface 522 can operate in accordance with a PtP communication protocol, such as the Intel® QuickPath Interconnect (QPI) or the like. In other embodiments, a different interconnect may be used.

In some embodiments, chipset 520 can be configured to communicate with processor 510, the processor N 505, display device 540, and other devices 572, 576, 574, 560, 562, 564, 566, 577, etc. Chipset 520 may also be coupled to the wireless antenna 578 to communicate with any device configured to transmit and/or receive wireless signals.

Chipset 520 connects to display device 540 via interface 526. Display 540 may be, for example, a liquid crystal display (LCD), a plasma display, cathode ray tube (CRT) display, or any other form of visual display device. In some embodiments of the disclosure, processor 510 and chipset 520 are integrated into a single SOC. In addition, chipset 520 connects to bus 550 and/or bus 555 that interconnect various elements 574, 560, 562, 564, and 566. Bus 550 and bus 555 may be interconnected via a bus bridge 572. In one embodiment, chipset 520 couples with a non-volatile memory 560, a mass storage device(s) 562, a keyboard/mouse 564, and a network interface 566 via interface 524 and/or 504, smart TV 576, consumer electronics 577, etc.

In one embodiment, mass storage device(s) 552 can include, but not be limited to, a solid state drive, a hard disk drive, a universal serial bus flash memory drive, or any other form of computer data storage medium. In one embodiment, network interface 566 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 7 are depicted as separate blocks within the system 500, the functions performed by some of these blocks may be integrated within a single semiconductor circuit or may be implemented using two or more separate integrated circuits. For example, although cache memory 516 is depicted as a separate block within processor 510, cache memory 516 or selected elements thereof can be incorporated into processor core 512.

It is noted that the system 500 described herein may be any suitable type of microelectronics packaging and configurations thereof, including, for example, system in a package (SiP), system on a package (SOP), package on package (PoP), interposer package, 3D stacked package, etc. Further, any suitable type of microelectronic components may be provided in the semiconductor packages, as described herein. For example, microcontrollers, microprocessors, baseband processors, digital signal processors, memory dies, field gate arrays, logic gate dies, passive component dies, MEMSs, surface mount devices, application specific integrated circuits, baseband processors, amplifiers, filters, combinations thereof, or the like may be packaged in the semiconductor packages, as disclosed herein. The semiconductor packages (for example, the semiconductor packages described in connection with any of FIGS. 1-5), as disclosed herein, may be provided in any variety of electronic device including consumer, industrial, military, communications, infrastructural, and/or other electronic devices.

In various embodiments, the devices, as described herein, may be used in connection with one or more processors. The one or more processors may include, without limitation, a central processing unit (CPU), a digital signal processor(s) (DSP), a reduced instruction set computer (RISC), a complex instruction set computer (CISC), a microprocessor, a microcontroller, a field programmable gate array (FPGA), or any combination thereof. The processors may also include one or more application specific integrated circuits (ASICs) or application specific standard products (ASSPs) for handling specific data processing functions or tasks. In certain embodiments, the processors may be based on an Intel® Architecture system and the one or more processors and any chipset included in an electronic device may be from a family of Intel® processors and chipsets, such as the Intel® Atom® processor(s) family or Intel-64 processors (for example, Sandy Bridge®, Ivy Bridge®, Haswell®, Broadwell®, Skylake®, etc.).

Additionally or alternatively, the devices, as described herein, may be used in connection with one or more additional memory chips. The memory may include one or more volatile and/or non-volatile memory devices including, but not limited to, magnetic storage devices, read-only memory (ROM), random access memory (RAM), dynamic RAM (DRAM), static RAM (SRAM), synchronous dynamic RAM (SDRAM), double data rate (DDR) SDRAM (DDR-SDRAM), RAM-BUS DRAM (RDRAM), flash memory devices, electrically erasable programmable read-only memory (EEPROM), non-volatile RAM (NVRAM), universal serial bus (USB) removable memory, or combinations thereof.

In example embodiments, the electronic device in which the disclosed devices are used and/or provided may be a computing device. Such a computing device may house one or more boards on which the devices may be disposed. The board may include a number of components including, but not limited to, a processor and/or at least one communication chip. The processor may be physically and electrically connected to the board through, for example, electrical connections of the devices. The computing device may further include a plurality of communication chips. For instance, a first communication chip may be dedicated to shorter range wireless communications such as Wi-Fi and Bluetooth, and a second communication chip may be dedicated to longer range wireless communications such as GPS, EDGE, GPRS, CDMA, WiMAX, LTE, EV-DO, and others. In various example embodiments, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, combinations thereof, or the like. In further example embodiments, the computing device may be any other electronic device that processes data.

According to example embodiments of the disclosure, there may be a method. The method may comprise: providing a portion of a semiconductor package including one or more electronic components attached to a board having one or more grounding pads proximate to the one or more electronic components; depositing a conductive adhesive layer to at least a portion of the one or more grounding pads; placing a shielding structure on the board, the shielding structure on the conductive adhesive layer and covering at least one of the one or more electronic components; and applying heat to the conductive adhesive layer at a first temperature for a first duration.

Implementation may include one or more of the following features. Applying the conductive adhesive layer may comprise applying the conductive adhesive layer using a spraying technique, a plating technique, a printing technique, or a dispensing technique. Applying the conductive adhesive layer may comprise applying the conductive adhesive layer using a spraying technique, wherein the spraying technique comprises an atomization technique, an electrospray technique, or an ultrasonic technique. Applying the conductive adhesive layer may comprise applying the conductive adhesive layer using a printing technique, wherein the printing technique comprises a vacuum printing technique. Applying the conductive adhesive layer may comprise applying the conductive adhesive layer using a dispensing technique, wherein the dispensing technique comprises an Auger dispensing technique or a jet dispensing technique. The application of heat may comprise photonic curing. The conductive adhesive layer may comprise sintering nanoparticles, non-sintering pastes, non-sintering inks, intermetallic compound forming material, or conductive particles. The conductive adhesive layer may comprise sintering nanoparticles, wherein the sintering nanoparticles comprise silver or copper. The conductive adhesive layer may comprise non-sintering pastes, wherein the non-sintering pastes comprise a metal. The conductive adhesive layer may comprise non-sintering inks, wherein the non-sintering inks comprise a metal. The conductive adhesive layer may comprise non-sintering pastes, wherein the non-sintering pastes comprise an epoxy acrylic adhesive system or a polymer system. The conductive adhesive layer may comprise non-sintering inks, wherein the non-sintering inks comprise an epoxy acrylic adhesive system or a polymer system. The conductive adhesive layer may comprise a intermetallic compound-forming material, wherein the intermetallic compound-forming material comprises a SnBiCu paste. The conductive adhesive layer may comprise conductive particles, wherein the conductive particles include fibers, flakes, nanoparticles, or graphite. The one or more electronic components may comprise an avalanche photodiode or a laser diode. The semiconductor package may comprise an optoelectronic package.

According to example embodiments of the disclosure, there may be a semiconductor package. The package may comprise: a conductive adhesive layer that is applied to at least a portion of one or more grounding pads of a semiconductor package, the conductive adhesive layer applied between at least two electronic devices disposed on the semiconductor package; a shielding structure that is applied to at least a portion of the one or more electronic components of the device, the shielding structure being in contact with at least one of the one or more grounding pads or the conductive adhesive layer; and wherein heat is applied to the conductive adhesive layer at a first temperature for a first duration.

Implementation may include one or more of the following features. The conductive adhesive layer may comprise sintering nanoparticles, non-sintering pastes, non-sintering inks, intermetallic compound forming, conductive particles. The conductive adhesive layer may comprise an intermetallic compound-forming material, wherein the intermetallic compound-forming material comprises a SnBiCu paste. The conductive adhesive layer may comprise sintering nanoparticles, wherein the sintering nanoparticles comprise silver or copper. The conductive adhesive layer may comprise non-sintering pastes or non-sintering inks, wherein the non-sintering pastes or the non-sintering inks comprise a metal. The conductive adhesive layer may comprise non-sintering pastes or non-sintering inks, wherein the non-sintering pastes or non-sintering inks comprise an epoxy acrylic adhesive system or a polymer system. The conductive adhesive layer may comprise conductive particles, wherein the conductive particles include fibers, flakes, nanoparticles, or graphite. The one or more electronic components may comprise an avalanche photodiode or a laser diode. The semiconductor package comprises an optoelectronic package.

According to the example embodiments of the disclosure, there may be an electronic device. The electronic device may comprise: a semiconductor package, comprising: a conductive adhesive layer that is applied to at least a portion of one or more grounding pads of a semiconductor package, the conductive adhesive layer applied between at least two electronic devices disposed on the semiconductor package; a shielding structure that is applied to at least a portion of the one or more electronic components of the device, the shielding structure being in contact with at least one of the one or more grounding pads or the conductive adhesive layer; and wherein heat is applied to the conductive adhesive layer at a first temperature for a first duration.

Implementation may include one or more of the following features. The conductive adhesive layer may comprise sintering nanoparticles, non-sintering pastes, non-sintering inks, intermetallic compound forming, conductive particles. The conductive adhesive layer may comprise an intermetallic compound-forming material, wherein the intermetallic compound-forming material comprises a SnBiCu paste. The conductive adhesive layer may comprise sintering nanoparticles, wherein the sintering nanoparticles comprise silver or copper. The conductive adhesive layer may comprise non-sintering pastes or non-sintering inks, wherein the non-sintering pastes or the non-sintering inks comprise a metal. The conductive adhesive layer may comprise non-sintering pastes or non-sintering inks, wherein the non-sintering pastes or non-sintering inks comprise an epoxy acrylic adhesive system or a polymer system. The conductive adhesive layer may comprise conductive particles, wherein the conductive particles include fibers, flakes, nanoparticles, or graphite. The one or more electronic components may comprise an avalanche photodiode or a laser diode. The semiconductor package comprises an optoelectronic package.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Other modifications, variations, and alternatives are also possible. Accordingly, the claims are intended to cover all such equivalents.

While the disclosure includes various embodiments, including at least a best mode, it is to be understood that many alternatives, modifications, and variations will be apparent to those skilled in the art in light of the foregoing description. Accordingly, the disclosure is intended to embrace all such alternatives, modifications, and variations, which fall within the scope of the included claims. All matters disclosed herein or shown in the accompanying drawings are to be interpreted in an illustrative and non-limiting sense.

This written description uses examples to disclose certain embodiments of the disclosure, including the best mode, and also to enable any person skilled in the art to practice certain embodiments of the disclosure, including making and using any apparatus, devices or systems and performing any incorporated methods and processes. The patentable scope of certain embodiments of the invention is defined in the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

The claimed invention is:

1. A semiconductor package, comprising:
a substrate having two or more electronic components and one or more grounding pads proximate to the two or more electronic components;
a conductive adhesive layer disposed on at least a portion of the one or more grounding pads, the conductive adhesive layer applied between the two or more electronic components; and
a shielding structure disposed over at least a portion of the two or more electronic component, the shielding structure being in contact with at least one of the one or more grounding pads or the conductive adhesive layer.

2. The semiconductor package of claim 1, wherein the conductive adhesive layer comprises sintering nanoparticles, non-sintering pastes, non-sintering inks, intermetallic compound forming material, or conductive particles.

3. The semiconductor package of claim 1, wherein the conductive adhesive layer comprises an intermetallic compound-forming material, wherein the intermetallic compound-forming material comprises a SnBiCu paste.

4. The semiconductor package of claim 1, wherein the conductive adhesive layer comprises sintering nanoparticles, wherein the sintering nanoparticles comprise silver or copper.

5. The semiconductor package of claim 1, wherein the conductive adhesive layer comprises non-sintering pastes or non-sintering inks, wherein the non-sintering pastes or the non-sintering inks comprise a metal.

6. The semiconductor package of claim 1, wherein the conductive adhesive layer comprises non-sintering pastes or non-sintering inks, wherein the non-sintering pastes or non-sintering inks comprise an epoxy acrylic adhesive system or a polymer system.

7. The semiconductor package of claim 1, wherein the conductive adhesive layer comprises conductive particles, wherein the conductive particles include fibers, flakes, nanoparticles, or graphite.

8. The semiconductor package of claim 1, wherein the one or more electronic components comprise an avalanche photodiode or a laser diode.

9. The semiconductor package of claim 4, further comprising an optoelectronic package, wherein the shielding structure covers at least a portion of the optoelectronic package.

10. A device, comprising:
a processor;
a memory device in communication with the processor, the memory device comprising:
a substrate having two or more electronic components and one or more grounding pads proximate to the two or more electronic components;
a conductive adhesive layer disposed on at least a portion of the one or more grounding pads, the conductive adhesive layer applied between the two or more electronic components; and
a shielding structure disposed over at least a portion of the two or more electronic component, the shielding structure being in contact with at least one of the one or more grounding pads or the conductive adhesive layer.

11. The device of claim 10, wherein the conductive adhesive layer comprises sintering nanoparticles, non-sintering pastes, non-sintering inks, intermetallic compound forming material, or conductive particles.

12. The device of claim 10, further comprising an optoelectronic package, wherein the shielding structure covers at least a portion of the optoelectronic package.
